(19) United States
(12) Patent Application Publication
(10) Pub. No.: US 2016/0215384 A1
(43) Pub. Date: Jul. 28, 2016

(54) DEPOSITION SOURCE INCLUDING REFLECTOR

(71) Applicant: SAMSUNG DISPLAY CO., LTD., Yongin-City (KR)

(72) Inventor: Heung Cheol JEONG, Yongin-City (KR)

(21) Appl. No.: 14/807,028

(22) Filed: Jul. 23, 2015

(30) Foreign Application Priority Data
Jan. 22, 2015 (KR) 10-2015-0010848

(51) Int. Cl. C23C 14/22; C23C 14/12

(52) U.S. Cl. CPC C23C 14/22; C23C 14/12

(57) ABSTRACT

A deposition source includes a reflector at an upper end of a frame, the reflector being in a form of a reflection plate in which nozzle apertures are located, the reflector having a sink inclined surface inclining toward a central portion in which the nozzle apertures are located, the nozzles apertures being recessed from an edge front end portion that is on the upper end of the frame.

### CROSS-REFERENCE TO RELATED APPLICATION

Korean Patent Application No. 10-2015-0010848, filed on Jan. 22, 2015, in the Korean Intellectual Property Office, and entitled: “Deposition Source Including Reflector,” is incorporated by reference herein in its entirety.

### BACKGROUND

1. Field

Embodiments relate to a deposition source including a reflector.

2. Description of the Related Art

Thermal physical vapor deposition is a technology to form an emission layer on a substrate surface by using vapor of a deposition material (for example, an organic material). The deposition material may be received in a vessel and heated to an evaporation temperature such that the vapor of the deposition material moves outside the vessel and condenses on a substrate to be coated.

Such a deposition process may be performed within a chamber with a pressure in a range of 10⁻⁷ to 10⁻² Torr, which includes a vessel receiving a deposition material and a substrate to be coated.

### SUMMARY

Embodiments are directed to a deposition source including a reflector at an upper end of a frame, the reflector being in a form of a reflection plate in which nozzle apertures are located, the reflector having a sink inclined surface inclining toward a central portion in which the nozzle apertures are located, the nozzles apertures being recessed from an edge front end portion that is on the upper end of the frame.

The deposition source includes nozzles. Each of the nozzle apertures may be formed as a circular hole or a slit hole having a diameter corresponding to an external body size of a respective one of the nozzles.

The reflection plate may further include a double installation port having a plurality of engaging grooves.

The reflection plate has a multi-plate structure including at least three plates.

Each plate of the multi-plate structure may engage at least one of the engaging grooves.

A distance between the engaging grooves of the double installation port may be in a range of 1 to 10 mm.

Each nozzle aperture may be in a form of a circular hole or a slit hole having the diameter corresponding to an external body size of the respective nozzle.

### BRIEF DESCRIPTION OF THE DRAWINGS

Features will become apparent to those of skill in the art by describing in detail exemplary embodiments with reference to the attached drawings in which:

FIG. 1 illustrates a cross-sectional view showing an inner configuration of a deposition apparatus in which a deposition source is installed.

FIG. 2 illustrates a cross-sectional view showing a point deposition source.

FIG. 3 illustrates a schematic view showing a reflector for a deposition source according to an exemplary embodiment.

FIG. 4 illustrates a cross-sectional view showing an installation state of a reflector for a deposition source according to another exemplary embodiment.

FIG. 5 illustrates a partial cross-sectional view schematically showing an installation state of a reflector for a deposition source according to another exemplary embodiment.

FIG. 6 illustrates a partial cross-sectional view schematically showing an installation state of a reflector for a deposition source according to another exemplary embodiment.

FIG. 7 illustrates a cross-sectional view schematically showing installation and operational relationship of the reflector for the deposition source according to the exemplary embodiment illustrated in FIG. 4.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

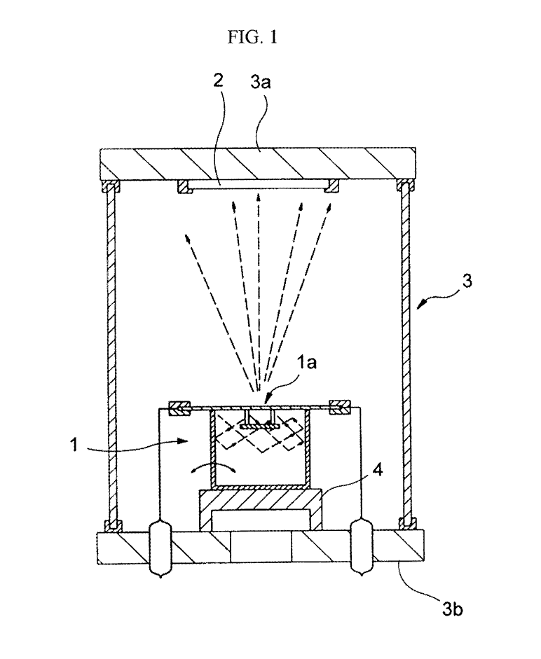

FIG. 1 illustrates a cross-sectional view showing an inner configuration of a deposition apparatus in which a deposition source is installed. In FIG. 1, a deposition source 1 is disposed inside a chamber 3 for a deposition apparatus, and a substrate 2 is disposed above the deposition source 1.

The substrate 2 on which an emission layer is deposited may be mounted in an upper plate 3a of the chamber. The substrate 2 may be fixed to the upper plate 3a or may be moveable in a width direction thereof, for example, as a straight movement in a horizontal direction.

The deposition source 1 may be mounted on an insulating structure 4 fixed to a bottom surface 3b of the chamber 3, and a power supply cable may be connected to the deposition source 1.

In FIG. 1, it is illustrated that a vapor efflux aperture 1a through which evaporated material gas is discharged from an inner space of the deposition source 1 to the outside toward the substrate is formed in an upper member of the deposition source 1.

A deposition source 1 may be classified as a point deposition source or a linear deposition source according to an overall shape thereof and a shape of the vapor efflux aperture 1a.

A point deposition source may have a cylindrical shape overall, and the vapor efflux aperture formed in the upper member may have a circular shape. In contrast, a linear deposition source may have a hexahedron shape and the vapor efflux aperture formed in the upper member may have a predetermined width in a length direction of the upper member.

Whether the point deposition source, the linear deposition source, or a combination thereof is used may be determined by taking into account deposition process conditions, substrate conditions, the form of a deposition film to be formed, or the like. The following description is given below by taking the point deposition source as an example.

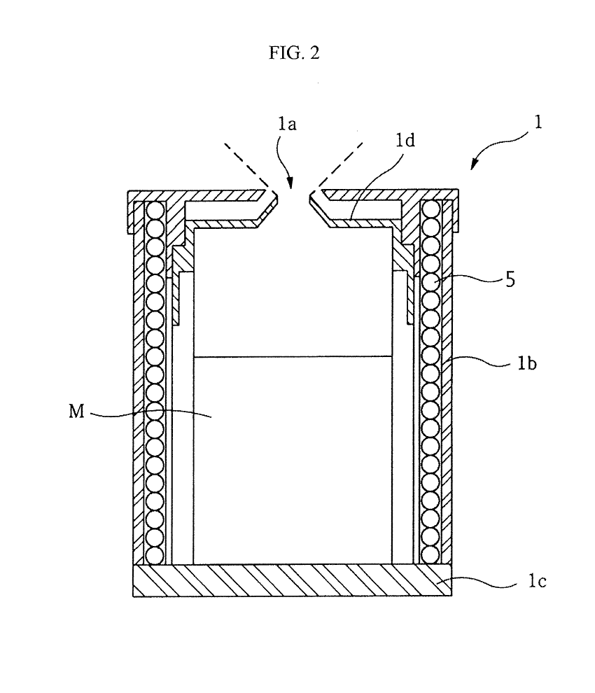

FIG. 2 illustrates a cross-sectional view of a point deposition source. As illustrated in FIG. 2, a point deposition source 1 may include a cylindrical sidewall member 1b, a circular plate-shaped bottom member 1c and an upper member 1d. An organic material that is a deposition material M may be received in an inner space defined by the upper member 1d, the sidewall member 1b, and the bottom member 1c.

A heater 5, such as a predetermined heating coil that heats the received deposition material M may be disposed within the sidewall member 1b. The heater 5 may be mounted on the sidewall member 1b along a height thereof so as to provide heat to the deposition material M.

The vapor efflux aperture 1a may be formed at a central portion of the upper member 1d. Vapor of the deposition material M heated and evaporated by the heater 5 mounted in the sidewall member 1 may be discharged through the vapor efflux aperture 1a toward the outside, that is, toward the substrate 2.

A diameter of the vapor efflux aperture 1a may be extremely small as compared to an overall diameter of the deposition source 1. Accordingly, the vapor efflux aperture 1a may function as a nozzle to spray a fluid at a high speed. When the vapor of the deposition material M generated in the inner space having a wide cross-section area passes through the vapor efflux aperture 1a having a narrow area, a flow speed of the vapor may be accelerated and a pressure of the vapor may be reduced, thereby achieving efficient spray of the material vapor.

An ambient temperature of the vapor efflux aperture 1a may be considerably lower than a temperature of the inner space. A separate heater may not installed in the upper member 1d, and also the vapor efflux aperture 1a is exposed to the outside. Accordingly, heat transferred to the upper member 1d from the inner space may be emitted to the outside, and the ambient temperature of the vapor efflux aperture 1a may be lower than a temperature of the inner space.

Due to the lower temperature of the vapor efflux aperture 1a, some of the material vapor discharged through the vapor efflux aperture 1a may solidify in the vicinity of the vapor efflux aperture 1a. As the deposition process progresses, a solidified material may be accumulated in the vicinity of the vapor efflux aperture 1a, having an undesirable influence on formation of a deposition film on a surface of the substrate 2. For example, the vapor efflux aperture 1a may become blocked by the solidified material of the material vapor.

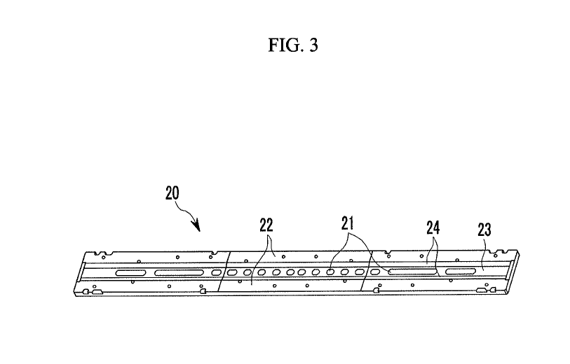

To address the above issues, an exemplary embodiment further including a reflector (as shown in the below FIGS. 3 to 7) in the deposition apparatus of FIG. 1 and the point deposition source of FIG. 2 above, shows how an accumulation of an organic particle material or nozzle blockage due to the progress of a deposition process may be prevented, and also how a solidification phenomenon due to a change in temperature in the vicinity of an aperture for the vapor discharge of organic particles may be prevented.

As shown in FIGS. 3 to 7, a reflector for a deposition source according to an exemplary embodiment may be disposed at an upper end of a frame 10 of the deposition source that receives predetermined organic particles. The reflector may be fin the form of a reflection plate 20 in which nozzle apertures are punched.

The deposition source according to the present embodiment may be configured to heat a deposition material received in the deposition source, for example, the organic particles, by an applied predetermined power, and to deposit material vapor of the organic particles on a surface of a relevant substrate by discharging the material vapor to the outside.

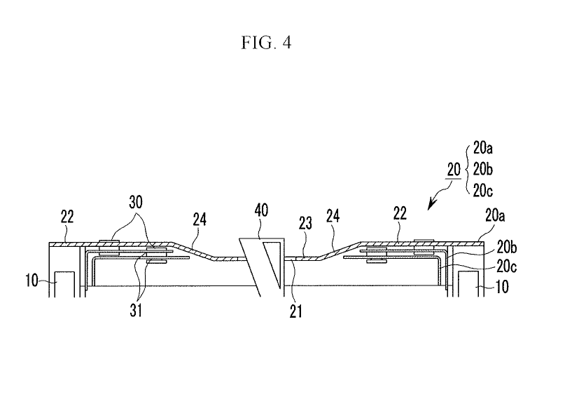

The nozzle aperture 21 may be formed to have a diameter corresponding to an external body size of a nozzle 40 as shown in FIGS. 3 and 4. For example, the nozzle aperture 21 may have a circular shape, a slit shape, a shape resulting from the mixing of the circular shape and the slit shape, or the like.

The reflection plate 20 may be formed on the upper end of the frame 10 of the deposition source and may include a predetermined heat-blocking layer in addition to the nozzle aperture 21.

The heat-blocking layer may be coated by an electro plating method. The heat-blocking layer may be formed by applying a material having a low thermal conductivity.

For example, the heat-blocking layer may be made of a ceramic-based material, such as Al₂O₃, TiO₂, SiC, or ZrO₂, or metal such as Mn or Ti.

The reflection plate 20 may include a structure in which a central portion in which the nozzle apertures 21 are punched is recessed at a predetermined depth. For example, the reflection plate 20 may include a sink inclined surface 24.

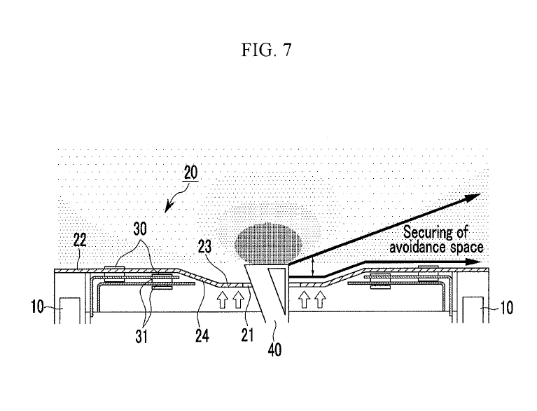

The sink inclined surface 24 is a type of inclined surface portion that is downwardly inclined to connect an edge front end portion 22 of the reflection plate 20, which is disposed on the upper end of the frame 10, with the central portion 23 in which the nozzle apertures 21 are punched. As shown in FIG. 7, the sink inclined surface 24 may have a technical configuration feature of securing a predetermined space for reduction and prevention of pollution due to the deposition material.

The sink inclined surface 24 may be bent twice from the edge front end portion 22 of the reflection plate 20 to the central portion 23, thereby allowing start and end borders of the sink inclined surface 24 to be clearly identified.

As described above, the recessed structure of the reflection plate 20 including the sink inclined surface 24 has technical effects of complementing a strong heat shielding function and preventing internal pollution of the deposition source due to intrusion of external material.

The reflection plate 20 may further include a predetermined double installation port 30.

The double installation port 30 may be used to connect and arrange the reflection plate 20 and to include multiple plates 20a, 20b, and 20c. The double installation port 30 may be implemented in various forms, such as a structure having a plurality of engaging grooves 31 formed on an external portion of a body thereof.

As shown in FIGS. 4 to 7, one of the plurality of engaging grooves 31 may connect and fix the uppermost reflection plate 20a and another of the engaging grooves 31 may fix and attach a lower plate, such as the middle plate 20b.

As described above, by using the double installation port 30, the reflection plate 20 according to an exemplary embodiment may form a multi-plate structure having at least three plates 20a, 20b, and 20c, as shown in FIGS. 4 to 6.

By using the reflection plate 20 having the multi-plate structure, it may be possible to minimize influence due to external air upon vapor heating for a deposition process and at the same time and to achieve heat loss of the deposition source.

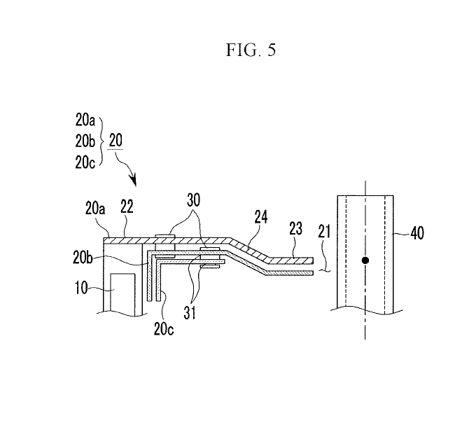

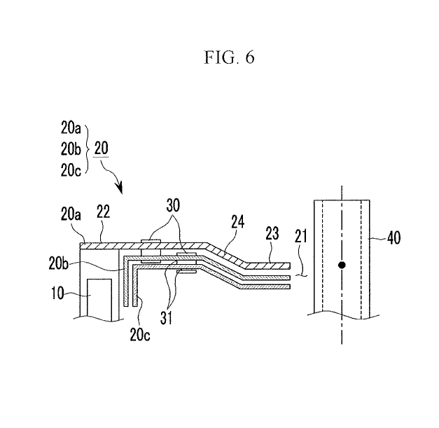

The recessed structure of the reflection plate 20 may be implemented in one or multiple plates of triple mirror plates as shown in FIGS. 4 to 6. For example, as shown in FIG. 4, the sink inclined surface 24 may be applied to only an uppermost reflection plate 20a and may be omitted from the remaining reflection plates 20b and 20c. As shown in FIG. 5, the sink inclined surface 24 may be applied to uppermost and middle reflection plates 20a and 20b and may be omitted from the remaining lowermost reflection plate 20c. As shown in FIG. 6, the sink inclined surface 24 is applied to all three reflection plates 20a, 20b, and 20c.

The recessed structure of the reflection plate 20 allows for improvement of an effect of avoiding and bounding the organic particle vapor during the deposition process.

The double installation port 30 may be implemented to have the engaging grooves 31 at a uniform interval. For example, the predetermined interval may be in a range of 1 to 10 mm.

In this case, an interval between the engaging grooves 31 may allow the reflection plates 20a, 20b, and 20c to be spaced apart from each other by a predetermined distance, thereby avoiding undesirable effects, such as heat loss due to external air during a deposition process, and also, contributing maintenance of an inner temperature of the frame 10.

The reflection plate 20 may be formed of a metal plate having a thickness of 0.2 to 5 mm. In the reflection plate 20 having the multi-plate structure, the nozzle aperture 21 having a diameter corresponding to an external size of a body of the nozzle 40 may be formed in respective reflection plates 20a, 20b, and 20c so as to have the same sizes, or may be formed in respective reflection plates 20a, 20b, and 20c so as to have a combination of different sizes.

By way of summation and review, a deposition source that is a vessel receiving a deposition material is generally includes walls or members made of an electrical resistive material, a temperature of which increases when a current passes therethrough. When a current is applied to the deposition source, the deposition material inside the deposition source is heated by radiant heat from the walls of the deposition source and conductive heat generated by contact with the walls.

A vapor efflux aperture through which evaporated material vapor is discharged to the outside is formed in an upper member of the deposition source.

A portion of the material vapor discharged through the vapor efflux aperture may solidify in the vicinity of the vapor efflux aperture. As a deposition process progresses, a solidified material due to the solidification phenomenon may accumulate in the vicinity of the vapor efflux aperture, thereby having an undesirable influence on formation of a deposition film on the substrate surface. For example, the vapor efflux aperture may become blocked by the solidified material of the material vapor.

In order to prevent the solidification phenomenon of the material vapor in the vicinity of the vapor efflux aperture, a cover fixed to the upper end of a sidewall member may be used to block emission of heat transferred from an inner space to the upper member to the outside and the upper member is capable of maintaining a temperature to some degree.

However, if the cover is made of a metal material, the cover may emit the heat transferred from the upper member to the outside. Also, the heat transfer from the upper member to the cover may continuously occur. As a result, an appropriate temperature may not be maintained even though a cover for blocking of heat emission is installed, and solidification of the material vapor may not be prevented in the vicinity of the vapor efflux aperture of the upper member.

Embodiments advance the art by providing a deposition source including a reflector that helps to prevent accumulation of an organic particle material or nozzle blockage according to the progress of a deposition process.

Embodiments also provide a deposition source that minimizes heat transfer to a reflection plate and simultaneously increases a spacing distance between reflection plates maximally, thereby preventing solidification phenomenon due to a change in temperature in the vicinity of an aperture for vapor discharge of organic particles.

With a deposition source including a reflector according to an exemplary embodiment, it may be possible to improve heat blocking effects, and simultaneously. prevent vapor of organic particles from being deposited on a surface of the reflection plate by arranging multiple plate structures to be spaced apart from by using the double installation port having double engaging grooves.

With a deposition source including a reflector according to an exemplary embodiment, it may be possible to secure a avoidance space between a spray aperture of a nozzle and a surface of a reflection plate by using a sink inclined surface of the reflection plate, thereby structurally solving process troubles, such as nozzle blockage due to vapor of organic particles during a deposition process.

With a deposition source including a reflector according to an exemplary embodiment, it may be possible to block heat emitted to the outside and simultaneously maintain an ambient temperature of an aperture for discharge of vapor of organic particles uniformly, by employing a triple- or multi-mirror plate structure.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof the present invention.

What is claimed is:

1. A deposition source, comprising
a reflector at an upper end of a frame, the reflector being in a form of a reflection plate in which nozzle apertures are located, the reflector having a sink inclined surface inclining toward a central portion in which the nozzle apertures are located, the nozzles apertures being recessed from an edge front end portion that is on the upper end of the frame.

2. The deposition source as claimed in claim 1, wherein:
the deposition source includes nozzles, and
each of the nozzle apertures is formed as a circular hole or a slit hole having a diameter corresponding to an external body size of a respective one of the nozzles.

3. The deposition source as claimed in claim 1, wherein:
the reflection plate further includes a double installation port having a plurality of engaging grooves.

4. The deposition source as claimed in claim 3, wherein:
the reflection plate has a multi-plate structure including at least three plates.

5. The deposition source as claimed in claim 4, wherein each plate of the multi-plate structure engages at least one of the engaging grooves.

6. The deposition source as claimed in claim 3, wherein:
a distance between the engaging grooves of the double installation port is in a range of 1 to 10 mm.

7. The deposition source as claimed in claim 3, wherein:
each nozzle aperture is in a form of a circular hole or a slit hole having the diameter corresponding to an external body size of the respective nozzle.
